(19) United States
(12) Patent Application Publication
(10) Pub. No.: US 2008/0230357 A1
(43) Pub. Date: Sep. 25, 2008

(54) GOLD-METAL OXIDE THIN FILMS FOR WEAR-RESISTANT MICROELECTROMECHANICAL SYSTEMS ("MEMS")

(75) Inventors: Richard P. Vinci, Easton, PA (US); Walter L. Brown, Basking Ridge, NJ (US); Thirumalesh Bannuru, Hillsboro, OR (US)

Correspondence Address: Saul Ewing LLP (Harrisburg);Attn: Patent Docket Clerk, Penn National Insurance Plaza, 2 North Second Street, Harrisburg, PA, 17101, US

(73) Assignee: LEHIGH UNIVERSITY, Bethlehem, PA (US)

(21) Appl. No.: 12/052,838

(22) Filed: Mar. 21, 2008

Related U.S. Application Data
(60) Provisional application No. 60/896,510, filed on Mar. 23, 2007.

(51) Int. Cl. H01H 59/00; H01B 1/02; C25D 5/00; C23C 14/34; H05K 3/00

(52) U.S. Cl. 200/181; 252/520.3; 252/520.21; 252/519.51; 205/80; 204/192.17; 427/96.1

(57) ABSTRACT

Provided herein are new methods for the fabrication of gold (Au) alloys and films containing metal or semimetal oxides such as oxides of vanadium (V), for example, Au—V₂O₅ for use in electrical, mechanical, and microelectromechanical systems (“MEMS”). An example embodiment provides a thin film of an alloy comprising Au—V₂O₅ in a MEMS for a contact switch. Also described herein are gold-metal oxide thin films for use in, e.g. wear-resistant MEMS. Measurements of contact force and electrical contact resistance between pairs of Au or Au—V films show that increased hardness and resistivity in the alloy films results in higher contact resistance and less adhesion than in pure Au.

### CROSS-REFERENCE TO RELATED APPLICATIONS

This application claims the priority of U.S. patent application No. 60/896,510, filed Mar. 23, 2007, the entire contents of which are incorporated herein by reference.

### STATEMENT REGARDING FEDERALLY SPONSORED RESEARCH OR DEVELOPMENT

Financial support was provided to the inventors at least in part by the National Science Foundation (“NSF”) under grant ECS-0322702, and the government of the United States may have certain rights herein.

### FIELD

This application describes gold thin films, methods of their manufacture, and uses thereof. More particularly, this application describes alloys of gold and at least one metal (or semimetal) oxide, thin films thereof, and MEMS contact switches having electrodes coated with such thin films.

### BACKGROUND

Microfabrication technology is used for the development of microelectromechanical systems (“MEMS”) technology for forming mechanical sensors, such as pressure sensors and accelerometers, and minute mechanical parts, such as microswitches and oscillators, and micromechanical systems. MEMS are used in a variety of consumer applications, including inkjet printers (which use piezoelectrics or thermal bubble ejection to deposit ink), accelerometers (which are used in automobiles to detect when an airbag should be deployed in collisions), personal media players and cell phones. Likewise, MEMS gyroscopes are used in automobile stability control systems, and pressure sensors are used as tire pressure sensors. Optical switching MEMS are used for switches and alignment mechanisms for data communications.

A typical MEMS switch is a switch having a minute structure formed on a substrate made of semiconductor or the like made by thin film manufacturing technologies. Such a MEMS switch has a fixed electrode on the substrate and a movable electrode having a structure such as a cantilever beam, a doubly-supported beam, a diaphragm and the like. The on/off action of the MEMS switch is performed by manipulating an electrostatic force or the like. Contact reliability is a critical feature for MEMS contact-type (ohmic) RF switches. See, e.g. Pruitt, et al. J. Micro-Electro-Mechanical Systems 3(2), 220 (2004), Majumder, et al. J. Sensors and Actuators A: Physical 93, 1926 (2001).

Good contacts should have low contact resistance, which is generally associated with pure, soft, noble metals. Good contacts should also have high resistance to wear degradation, which is enhanced by increased hardness, usually to the detriment of contact resistance. Bulk metal contacts are often fabricated from binary and ternary alloys that are heat treated to attain optimum properties. Furthermore, high contact forces are often required to develop low contact resistance by surface scrubbing. Thin film electrodes are not as easy to heat treat because the thermal processing profile of a MEMS device is often determined by factors other than the needs of the contact electrode. Also, MEMS contact forces are typically quite low and cannot be relied upon to establish good metal-to-metal contact in the presence of unwanted insulating surface films.

Solid solution alloys of Au and Pt have been shown to offer a reasonable compromise between low contact resistance and high wear resistance. Coutu, et al. J. Micromech. Microeng. 14, 1157 (2004). However, Pt is expensive and solid solution strengthening is less effective at increasing hardness than strengthening mechanisms that utilize multiple phases. Alternatively, gold thin films may be used for contact-type microswitches due to their chemical inertness and attractive electrical properties. See, e.g. Majumder, et al., Sensors and Actuators A: Phys. 93, 1926 (2001); Pruitt, et al. J. of Micro-Electro-Mechanical Systems 3(2), 220 (2004); Paul G. Slade, “Electrical Contacts: Principles and Applications,” ISBN 0-8247-1934-4, (Marcel Dekker Inc., New York, 1999). However, pure Au is mechanically soft and is therefore susceptible to failure by cold welding and wear.

Accordingly, a continuing and unmet need exists for new and improved materials, such as thin films for use in, e.g. contact switches in MEMS, that are free of the above-noted deficiencies.

### SUMMARY

Provided herein are new methods for the fabrication of gold (Au) alloys and films containing gold and at least one metal (or semimetal) oxide for use in electrical, mechanical, and microelectromechanical systems (“MEMS”). An exemplary embodiment provides a thin film of an alloy comprising gold and a vanadium oxide, such as Au—V₂O₅, in a MEMS for a contact switch. Also described herein are gold-metal oxide alloys and thin films for use in, e.g. wear-resistant MEMS.

Oxides of vanadium (V), zirconium (Zr), and aluminum (Al), among others, are compatible with gold to form alloys and thin films having the desirable properties of low resistivity and durable wear described herein. By way of illustrative example, the electrical and mechanical properties of Au—V and Au—VOₓ alloys in an example system are disclosed. However, films comprising other gold-metal (and semimetal) oxides may include those of the general formulae Au—VₓO_{y}, Au—ZrₓO_{y}, and Au—AlₓO_{y}, wherein x and y depend on the oxidation state of the metal (e.g., 1, 2 or 3).

Vanadium forms a solid solution up to 13 atomic % V (4 weight %) in Au at room temperature. See, e.g. T. B. Massalski, “Binary Alloy Phase Diagrams,” ISBN: 0871702614, 2^{nd} edition (Amer. Soc. Metals, Ohio, USA, 1990). Moreover, vanadium can be easily oxidized, raising the possibility of creating ODS alloys with VOₓ nano-dispersions. This would be impossible to achieve in bulk gold via internal oxidation due to the low oxygen solubility, see, J. L. Meijering, in: H. Herman (Ed.), “Advances in Materials Research,” 514 vol. 5, Wiley-Interscience, New York, 1971, p. 1, but—as demonstrated herein—it is feasible in thin films via reactive physical vapor deposition. Vinci, et al. “Key Engineering Materials,” 345-46, 2007, pp. 735-40. As described in more detail herein below, pure Au films, Au—V solid solutions with 0.25 to 4.6 at % V, and ODS Au—VOₓ with 2.3 and 4.0 at % V were prepared by co-sputter deposition, then characterized using nanoindentation and four-point probe resistivity techniques to evaluate their suitability as electrode materials.

In an exemplary embodiment, provided herein are methods for preparing and using an alloy thin film that includes gold and at least one oxide of a metal or semimetal, such as vanadium. Preparation can involve, for example, planar DC magnetron sputtering of the noble metal and vanadium in a co-sputtering arrangement onto a thin layer adhesion promoter such as titanium (Ti).

In another embodiment, provided herein is a method for providing a durable low-resistivity contact layer onto a substrate. For example, the layer may include a gold and vanadium oxide(s) film applied to a substrate such as silicon (Si) or stainless steel.

The low-resistivity alloy films described herein have greater hardness and durability than gold alone. The coating and its methods of use in electrical applications such as MEMS switches provide superior performance over time through increased hardness, contact force and load capacity, and resistance to contact degradation and wear. An economic advantage is realized through reduced gold content and a longer expected performance life, thus fulfilling a longstanding but unmet commercial need for cost-effective, durable, low-resistivity materials suitable for use in MEMS and other intricate electrical and mechanical applications.

By way of example, a MEMS switch may be an electronic device including a microelectromechanical systems element at a first side of a substrate, which MEMS element includes a first electrode and a second electrode that is movable between at least a closed and an opened position, the second electrode separated from the first electrode by, e.g. an air gap, when in its opened position. Such electrodes may be coated with a thin gold-metal (or semimetal) oxide film as described herein.

Additional features may be understood by referring to the accompanying drawings, which should be read in conjunction with the following detailed description and examples.

### DESCRIPTION OF THE DRAWINGS

FIG. 1 is a schematic diagram of electrical/mechanical test specimens in accordance with an example embodiment hereof.

FIGS. 2-3 illustrate the compressive load and contact resistance of pure Au (FIG. 2) and Au-4.6% V (FIG. 3) electrodes plotted as a function of time for a single contact cycle.

FIG. 4 illustrates the Rutherford Back Scattering (“RBS”) spectrum showing a homogenous distribution of V in a 2.2 at % Au—VOₓ thin film. The Ti peak is from a thin adhesion layer of Ti under the Au/V film. The vertical scale is logarithmic.

FIG. 5 shows the chemical shifts of V2p spectral lines observed in Au—VOₓ thin film with 2.3 at % V.

FIGS. 6-7 illustrate the electrical resistivity (FIG. 6) and hardness (FIG. 7) versus at % V in Au, Au—V, and Au—V₂O₅ thin films. Both properties show increasing trend with V content, but the hardness improvement is accompanied by a smaller resistivity penalty for the Au—V₂O₅ films.

### DETAILED DESCRIPTION AND EXAMPLE EMBODIMENTS

MEMS devices are typically made, at least in part, by depositing thin films of material onto a substrate. As used herein, “film” includes any deposit of a material made onto any substrate, regardless of whether the material is continuous or discontinuous with itself or other material deposited on the substrate, regardless of whether the material is permanently adhered to the substrate or removeable therefrom, regardless of the method of application, and regardless of the composition of the material deposited. Such films may have a thickness anywhere between a few nanometers to about 100 micrometers (typically in the range of about 10 nanometers to about 25 micrometers), and films of such dimension are sometimes referred to herein as “thin” films. Suitable exemplary deposition processes for applying materials comprising metals, oxides, and alloys, for example to form thin films on substrates, include electrodeposition (e.g., electroplating), physical vapor deposition (“PVD”) (e.g., sputter deposition), and chemical vapor deposition (“CVD”).

In an example embodiment, films of Au, Au—V, and Au—V₂O₅ (and other oxides of vanadium) were prepared by planar DC magnetron sputtering according to the following procedure. Although this example method is described with respect to oxides of vanadium, one skilled in the art will readily appreciate that other metals and metal oxides (and semimetals and semimetal oxides) may be employed by similar methods.

A thin Ti layer was deposited as an adhesion promoter prior to deposition of the metal film. The fabrication of the Au—V and Au—V₂O₅ films each employed two targets: 99.999% pure Au and 99.999% pure V, in a co-sputtering arrangement. In principle, one could also employ a single target composed of a gold alloy that corresponds to the composition of the desired film. When using two targets, the relative composition of the resulting film(s) can be varied by modulating the power supplied to each target. The power to two guns was adjusted to create a range of film compositions, as further described herein. Ar at 4 mTorr was the process gas for all films. For the fabrication of the Au—V₂O₅ films, O₂ was added to the process gas stream at a pressure of 0.1 mTorr for reaction with the V during deposition.

Two types of substrates were coated simultaneously in each deposition run. The first substrate was an oxidized Si die, adhered to a printed circuit board. The second substrate was a stainless steel ball, ⅛″ diameter, also mounted to a printed circuit board. The ball's sphericity and smoothness was Class 3, the best surface finish commercially available. When mounting to the printed circuit boards, the balls were examined visually to ensure that the smoothest region of each would act as the eventual contact surface. After coating with the desired film, small wires were attached to the coated dies, balls, and printed circuit boards to enable four-point electrical resistance measurement of a contact as it closed and opened.

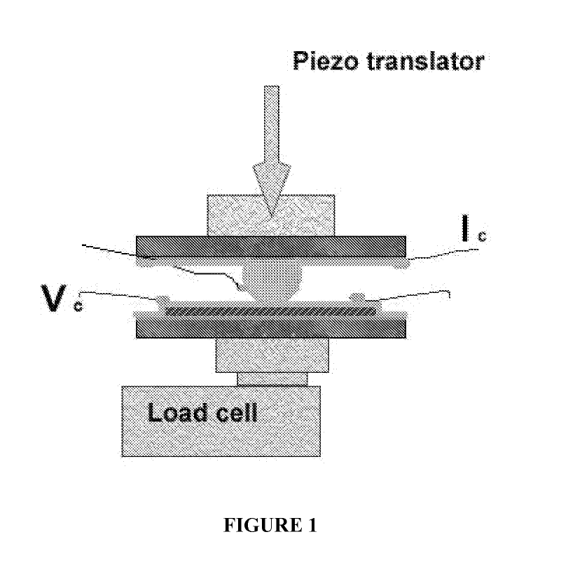

Referring to the attached Drawings, FIG. 1 is a schematic diagram of electrical/mechanical test specimens. The upper specimen is a stainless steel ball mounted onto a printed circuit board. The lower specimen is a silicon die also mounted onto a printed circuit board. In the film-forming method described above, both sides of each contact are coated with a film comprising either Au, and Au-alloy, or Au-metal oxide at substantially the same time, after which wires are attached for four-point electrical resistance measurement. The upper specimen is rigidly attached to a piezoelectric actuator used to control the displacement. The lower specimen is attached to a load cell for load measurement during contact.

Additional oxidized Si dies were coated at substantially the same time as the other Si dies and stainless steel balls, and were used as controls for characterization of composition, electrical, and mechanical properties of the films. Composition was evaluated using Rutherford Backscattering (“RBS”), Nuclear Elastic Resonance (“NER”), and X-ray Photoelectron Spectroscopy (“XPS”). Electrical resistivity was measured with an Alessi probe test station fitted with C4S-54/5 four-point probe head (Cascade Microtech, Beaverton Oreg.). Several measurements were made for each composition, and the results were averaged. Nanoindentation hardness was measured using a Hysitron Triboscope with a 50 nm nominal radius Berkovich diamond tip, integrated onto a DI MM-AFM platform. An average value of hardness was calculated from several indents performed on each specimen under identical loading conditions. All films were indented to less than 10% of their thickness to reduce possible effects from the substrate, and hardness was calculated according to standard practice.

The contact test arrangement included a ball-on-flat geometry to approximate Herztian contact. Electrical and mechanical contact behavior was determined using a custom-built apparatus consisting of a stiff load frame, a piezoelectric actuator (Polytec PI P-239.47 with 60 μm travel), and a load cell (Transducer Techniques GSO-10). The ball-type specimen was mounted rigidly to the actuator for displacement-controlled closure and reopening of the contact with a displacement resolution of 1.2 nm. The Si die-type specimen was mounted to a load cell with a load resolution of ±0.05 mN. A 2 V power supply was connected to the “outer” pair of wires through a 100Ω resistor (one wire for each PC board) and the voltage across the “inner” pair of contacts in a four-point resistance measurement configuration was measured using LabVIEW hardware and software. Resistance resolution is estimated to be ±0.006Ω. Displacement of the actuator and attached ball was controlled by LabVIEW, which was also used for data collection of load. The sampling rate was 30 S/s. The displacement rate was set to 60 nm/s until a compressive load of approximately 2 mN was achieved, at which point the motion of the actuator was briefly halted then reversed to retract the ball at the chosen rate.

RBS analysis of the pure Au films showed that there were no significant contaminants, and that the provided Ti adhesion layer was not interdiffused with the Au. RBS also showed that the alloy films were uniform in V content throughout the thickness. The presence of oxygen in the reactively-sputtered films was confirmed with NER, and XPS further indicated that the oxidized films possessed V₂O₅ with no detectible metallic V. The composition results are summarized in Tables 1 and 2, below, along with resistivity and hardness values.

TABLE 1
Electrical and mechanical properties of the pure Au and Au—V solid solution alloy films, as
well as contact resistance values measured at a peak load of 2 mN.

| Composition | Resistivity, ρ | Hardness, H | | Predicted Minimum | True Minimum |
|---|---|---|---|---|---|
| (at % V) | (μΩ-cm) | (GPa) | Δρ/ΔH | Contact Resistance (Ω) | Contact Resistance (Ω) |
| 0 | 6.1 | 2.52 | — | 0.06 | 0.18 |
| 0.25 | 10.8 | 2.61 | 52 | 0.11 | 0.48 |
| 0.65 | 22.5 | 2.91 | 42 | 0.24 | 0.58 |
| 1.4 | 23.6 | 2.65 | 135 | 0.24 | na |
| 2.2 | 40.0 | 2.83 | 109 | 0.42 | na |
| 4.6 | 65.0 | 3.46 | 63 | 0.76 | 1.80 |

TABLE 2
Electrical and mechanical properties of the Au—V₂O₅ dispersion strengthened films, with
estimated contact resistance values calculated from the Au and Au—V behavior.

| Composition | Resistivity, ρ | Hardness, H | | Predicted Minimum | Estimated True |
|---|---|---|---|---|---|
| (at % V) | (μΩ-cm) | (GPa) | Δρ/ΔH | Contact Resistance (Ω) | Contact Resistance (Ω) |
| 2.3 | 12.0 | 3.28 | 7.8 | 0.14 | 0.41 |
| 4.0 | 17.7 | 4.00 | 7.8 | 0.22 | 0.60 |

Electrical measurements indicated steadily increasing resistivity with increasing V concentration in both the solid solution and oxidized films. This trend is believed to result from the V and V₂O₅ in the Au matrix both acting as electron scattering centers. The rise in resistivity is noticeably slower for the V₂O₅ cases, however, consistent with dispersed oxide particles in a nearly solute-free matrix. Nanoindentation results also showed increasing hardness in all alloy films, which is a desirable characteristic. The rate of change was greater for the V₂O₅ films, which is associated with more effective trapping of dislocations by oxide particles than by individual solute atoms.

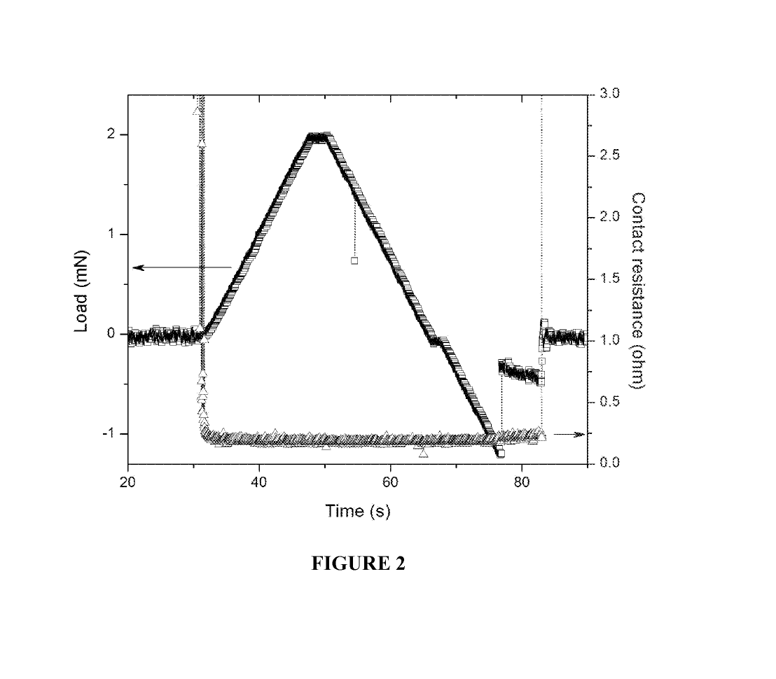

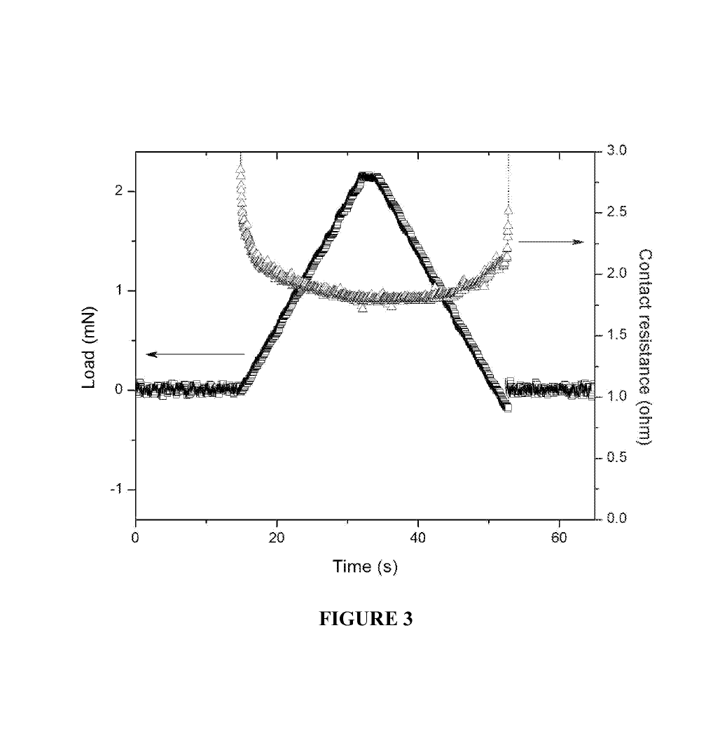

Testing of electrical contact resistance and contact force was carried out with pure Au and with Au-4.6% V in solid solution. The results of these tests are shown in FIGS. 2-3, and the measured average minimum contact resistances are listed in Table 1. As seen in FIG. 2, the pure Au contacts develop a low contact resistance almost immediately after contact is first established during the contact closure segment of the test. The initial rise in compressive load corresponds closely with the initial drop in resistance, indicating that no surface anomalies (e.g., insulating films or large asperities) exist in the region tested, that plastic deformation of small asperities occurs readily, and that the corresponding contact area increases rapidly as load increases. The contact resistance continues to drop slightly throughout the loading segment, but quickly approaches a steady value. During the contact opening segment the compressive load falls linearly, then the load becomes tensile due to significant sticking forces between the two sides of the contact.

There are three important features in the opening load curve illustrated in FIG. 2: (1) A small change in slope near zero load that indicates a partial separation of a small part of the contact; (2) a large decrease in tensile load indicative of a large unsticking or plastic deformation event; and (3) a somewhat smaller decrease in tensile load corresponding to complete opening of the contact. The large tensile load decrease is likely to be the result of a filament being drawn out of the surfaces, in which case the final decrease in tensile load may correspond to fracture of the bridging Au filament. Note that the contact resistance curve that shows small increases in resistance associated with each of the first two unsticking events, and a large increase in resistance (to a complete open circuit) associated with the third and final event.

Still referring to the attached Drawings, compressive load and contact resistance of pure Au (FIG. 2) and Au-4.6% V (FIG. 3) electrodes are plotted as a function of time for a single contact cycle. As the contact closes and the compressive load increases linearly, the contact resistance for the pure Au rapidly decreases and approaches a constant value. The contact resistance for the alloy electrodes decreases gradually and attains its minimum when the loading stops. Upon retraction of the spherical electrode the load falls linearly in both cases, then becomes tensile, indicating sticking of the electrodes. For the pure Au films, the sticking force is very strong compared to that of the alloy films. When a sufficient tensile load is established the contacts separate and the contact resistance rises. This occurs in two stages for the pure Au, as indicated by the pair of load drops and matching increases in contact resistance, and in a single stage for the alloy.

FIG. 3 shows similar behavior in the case of the Au-4.6% V film, but with several differences. First, the decrease in contact resistance is more gradual than in the pure Au case. The minimum measured value is reached at the maximum 2 mN compressive load; presumably the contact resistance would have continued to decrease if the maximum load had been larger. Upon retraction of the upper electrode, the contact resistance immediately responds by increasing. Also, only a small tensile force is established as the electrodes separate, and a single unsticking event is sufficient to fully open the contact. These results are all consistent with a harder film that resists plastic deformation of asperities, and therefore has a smaller rate of true contact area growth as compared to the pure Au. The increased hardness has also resulted in decreased sticking between the surfaces, and may prevent the pull-out of surface filaments during the opening process. Accordingly, the lifetime of a switch using the Au-4.6% V alloy would be greater than one using pure Au, but with a large corresponding increase in contact resistance.

The results attained from the Au and Au—V films also imply that the Au—V₂O₅ films, with their greater hardness values for a given V concentration, exhibit lower sticking forces than either of the tested pure Au and Au-alloy films. At first glance this would seem to also imply a poor contact resistance, but the low resistivity associated with the V₂O₅ particles should ameliorate this situation. The relative change in resistivity and hardness compared to pure Au is summarized in Tables 1 and 2, demonstrating that the resistivity increase per unit hardness increase is highly favorable for the Au—V₂O₅ films. The predicted minimum contact resistances for the Au—V and Au—V₂O₅ films are also listed in Table 1 and 2, respectively, assuming a contact force of 2 mN. These values are calculated using the Holm equation, as follows:

$${R}_{c} = \frac{ρ}{2} \sqrt{\frac{H π}{{F}_{c}}}$$

where R_{c} is contact resistance, ρ is film resistivity, H is hardness, and F_{c} is contact force. See, Slade, “Electrical Contacts,” ISBN 0-8247-1934-4 (Marcel Dekker Publishers, New York). The actual contact resistance values are greater than the predicted values, consistent with the observations in other, similar studies. See, e.g. Coutu, et al. J. Micromech. Microeng. 14, 1157 (2004). Despite this discrepancy, the calculated values can be used for comparison among the alloys. Based on the Holm relationship, the Au—V₂O₅ films with 2.3 and 4.0 at % V should have similar contact resistance values to the Au—V films with 0.25 and 0.65 at % V, but presumably would exhibit much longer lifetimes.

Experimental contact resistance values for the Au—V₂O₅ films can be estimated based on the relationship that exists between the predicted contact resistance and the actual contact resistance values of Au and Au—V shown in Table 1. A linear fit to the data gives a slope of 2.2 and an intercept of 0.11Ω, leading to estimated contact resistance values of 0.41 and 0.60Ω for the Au—V₂O₅ films tested under identical conditions, as shown in Table 2.

By way of further example, Au—V solid solution and Au—V₂O₅ dispersion strengthened films have been fabricated using simple magnetron sputtering techniques. Both sets of alloy films have improved hardness compared to pure Au. In the case of the solid solution films, contact testing shows the desired effect of increased hardness on decreasing the tendency of the contacts to stick. However, the associated contact resistance rise is large. The large rise in hardness and limited rise in film resistivity associated with oxidizing V in Au to form Au—V₂O₅ films shows promise for reduced sticking without such a large contact resistance penalty. This combination of properties is attractive for contact applications, and provides significant motivation for further study of the Au—V₂O₅ system.

Accordingly, provided herein are new thin films comprising an alloy of gold and at least one of an oxide of a metal or an oxide of a semimetal. In an embodiment, the at least one of an oxide of a metal or an oxide of a semimetal is selected from the group consisting of oxides of vanadium (V), aluminum (Al), zirconium (Zr), silicon (Si), magnesium (Mg), beryllium (Be), lithium (Li), boron (B), hafnium (Hf), thorium (Th), calcium (Ca), chromium (Cr), manganese (Mn), titanium (Ti), scandium (Sc), yttrium (Y), molybdenum (Mo), tungsten (W), zinc (Zn), niobium (Nb), tantalum (Ta), cerium (Ce), lanthanum (La), and combinations thereof. For example, the oxides of vanadium may be selected from the group consisting of V₂O₅, V₂O₃, VO₂, and VO.

In an example embodiment, the film comprises less than about 99.9 at % gold and at least about 0.1 at % (atomic %) metal or semimetal. In another example embodiment, the film comprises from about 1 at % to about 20 at % metal or semimetal. Typically, the film has a thickness of from about 10 nm to about 25 μm.

Also provided herein is a method of making a film comprising a step of simultaneously or contemporaneously depositing (e.g., co-depositing) gold and at least one metal or semimetal in an oxidative environment onto a substrate to thereby produce a film comprising an alloy of gold and at least one of an oxide of a metal or an oxide of a semimetal. The oxidative environment may comprise oxygen (O₂) such that at least a portion of the metal or semimetal is at least partially oxidized in situ to an oxide of the metal or an oxide of the semimetal. In a typical embodiment, the film develops by nucleation and growth of the metal oxide particles within the surrounding gold matrix, as opposed to being a mixture of gold and metal oxide particles produced by mechanical mixing.

The depositing step may be selected from the group consisting of electrodeposition, physical vapor deposition, and chemical vapor deposition. For example, the physical vapor deposition may include sputter deposition. In another embodiment, the gold and the metal or semimetal may be deposited in a co-sputtering arrangement in the presence of oxygen (O₂). The at least one metal or semimetal may be selected from the group consisting of vanadium (V), aluminum (Al), zirconium (Zr), silicon (Si), magnesium (Mg), beryllium (Be), lithium (Li), boron (B), hafnium (Hf), thorium (Th), calcium (Ca), chromium (Cr), manganese (Mn), titanium (Ti), scandium (Sc), yttrium (Y), molybdenum (Mo), tungsten (W), zinc (Zn), niobium (Nb), tantalum (Ta), cerium (Ce), lanthanum (La), and combinations thereof. The substrate may include or be coated with an adhesion promoter (e.g., titanium).

Further provided herein are alloys of gold and at least one of an oxide of a metal or an oxide of a semimetal, wherein the at least one of an oxide of a metal or an oxide of a semimetal is selected from the group consisting of oxides of vanadium (V), aluminum (Al), zirconium (Zr), silicon (Si), magnesium (Mg), beryllium (Be), lithium (Li), boron (B), hafnium (Hf), thorium (Th), calcium (Ca), chromium (Cr), manganese (Mn), titanium (Ti), scandium (Sc), yttrium (Y), molybdenum (Mo), tungsten (W), zinc (Zn), niobium (Nb), tantalum (Ta), cerium (Ce), lanthanum (La), and combinations thereof, and the alloy comprises less than about 99.9 at % gold and at least about 0.1 at % metal or semimetal. The oxides of vanadium may be selected form the group consisting of V₂O₅, V₂O₃, VO₂, and VO.

In an example application, a contact switch may include at least two conductive electrodes, wherein at least a portion of at least one of the electrodes is coated with a film comprising an alloy of gold and at least one of an oxide of a metal or an oxide of a semimetal. The at least one of an oxide of a metal or an oxide of a semimetal is selected from the group consisting of oxides of vanadium (e.g., V₂O₅, V₂O₃, VO₂, and VO), aluminum (Al), zirconium (Zr), silicon (Si), magnesium (Mg), beryllium (Be), lithium (Li), boron (B), hafnium (Hf), thorium (Th), calcium (Ca), chromium (Cr), manganese (Mn), titanium (Ti), scandium (Sc), yttrium (Y), molybdenum (Mo), tungsten (W), zinc (Zn), niobium (Nb), tantalum (Ta), cerium (Ce), lanthanum (La), and combinations thereof. The film may include less than about 99.9 at % gold and at least about 0.1 at % metal or semimetal. For example, the film may have a thickness of from about 10 nm to about 25 μm.

Additional embodiments are further exemplified by the following examples, which should not be construed as limiting.

### EXAMPLES

In the following example, all films were prepared by DC magnetron co-sputtering on silicon substrates. Some substrates were coated by a thick thermal oxide layer to avoid any substrate influence during electrical testing. Commercially available 3″ circular, pure (99.995%) Au and V targets were utilized. The base pressure of the sputtering chamber was in the mid 10⁻⁸ Torr range. DC power to the V gun was pulsed via a Small Package Arc Repression Circuit-Low Energy (Sparc-LE) unit operated in Self-Run Mode in order to prevent arcing from possible target oxidation. This automatically reverses the target voltage for 5 μs at a 20 kHZ rate (while the unit also actively eliminates arcs). The power settings on the individual Au and V guns were adjusted in order to attain the desired V composition in the films. The Si substrate was rotated to ensure homogenous composition and uniform film thickness. A 10 nm thick Ti film, deposited using a third gun and pure Ti target, acted as an adhesion layer between the Si substrate and the deposited Au—V films.

Pure Au and five Au—V solid solution compositions from approximately 0.25 to 5 at % V were produced at a working pressure of 4 mTorr with pure Ar as the process gas. Two Au—VOₓ compositions of approximately 2 and 4 at % V were fabricated by reactive co-sputtering in an Ar—O₂ mixture. Before deposition, the V target was presputtered in pure Ar for 10 min at 4 mTorr. Then, in the case of the Au—VOₓ films, the Ar plasma was turned off and oxygen was introduced to bring the partial pressure of oxygen to 0.1 mTorr. The V target was further presputtered in the Ar+O mixture for 5 min while the Au target was pre-sputtered for 1 min. The purpose was to clean the V target in Ar, then condition it after 0 introduction. Two thicknesses of each film type were fabricated: approximately 100-150 nm for chemical analysis, and 500 nm for electrical and mechanical characterization.

Rutherford Backscattering Spectrometry (“RBS”) with 1.44 MeV He²⁺ ions was used to determine the composition of the alloy films. The thickness of films was restricted to less than 150 nm to reveal the RBS signal most clearly. For the case of multi-component films, the atomic composition of the film can be deduced from the fact that the backscattering spectrum contains a peak for each element. For a film of composition AₘBₙ, the relative atomic ratio is given by the following formula:

m/n=[A_{A}/Z²_{A}]/[A_{B}/Z²_{B}]

where A_{A} and A_{B} are the area of signal A and B in the spectrum after background subtraction. Z is the atomic number of the element.

The two Au—VOₓ films were also characterized by Nuclear Elastic Resonance (NER), and X-ray Photoelectron Spectroscopy (“XPS”). Normal RBS gives the vanadium content and depth distribution but is not sensitive enough to detect oxygen. NER scattering has enhanced sensitivity for detecting oxygen in the film independent of its chemical bonding state. NER spectra were obtained near the upper and lower interfaces of the thin film by adjusting the incident He²⁺ energy to put oxygen into nuclear elastic resonance at a particular depth.

The bonding characteristics of V and O were determined using an angle-resolved spectrometer SCIENTA ESCA-300 XPS system equipped with monochromatic Al Kα 1.48 keV radiation and a concentric hemispherical electron analyzer. The X-rays illuminate a line of 1×5 mm² and the detector analyzes an area of approximately 1 mm² in the center. The spectra were recorded at two different angles of X-ray incidence. Normal incidence XPS spectrum provided oxidation state predominantly in the near surface bulk. Glancing incidence XPS spectrum at 15° provided information mainly from the top few surface layers.

The electrical resistivity, grain size, and hardness of the films were determined by four-point probe, AFM, and depth sensitive nanoindentation methods respectively. An Alessi probe test station fitted with C4S-54/5 four-point probe head (Cascade Microtech, Beaverton Oreg.) was used for electrical characterization. The spacing between any two adjacent probes is 1000 μm while the tip radius of the probes is 125 μm. Sheet resistance of the pure and alloy films was determined from the following formula:

Rₛ=4.53×V/I

Bulk resistivity, determined by the following formula, was extracted based on the film thickness as measured by SEM and AFM:

ρ=Rₛt

where ρ is resistivity, Rₛ is sheet resistance from four-point probe, and t is film thickness. The average grain size in the films was also determined from SEM and AFM imaging, an approach that agrees well with TEM for this particular class of films. Nanoindentation was performed using a Hysitron Triboscope on a DI MM-AFM platform. A Berkovich diamond tip with 50 nm nominal radius was used. Several indents at identical loading conditions were made and an average value of hardness was calculated. All the films were indented to less than 10% of their thickness to reduce possible effects from the substrate. Hardness was calculated according to the standard practice. See, e.g. Fischer-Cripps, “Nanoindentation,” ISBN: 0-387-95394-9 (Springer series, 2002).

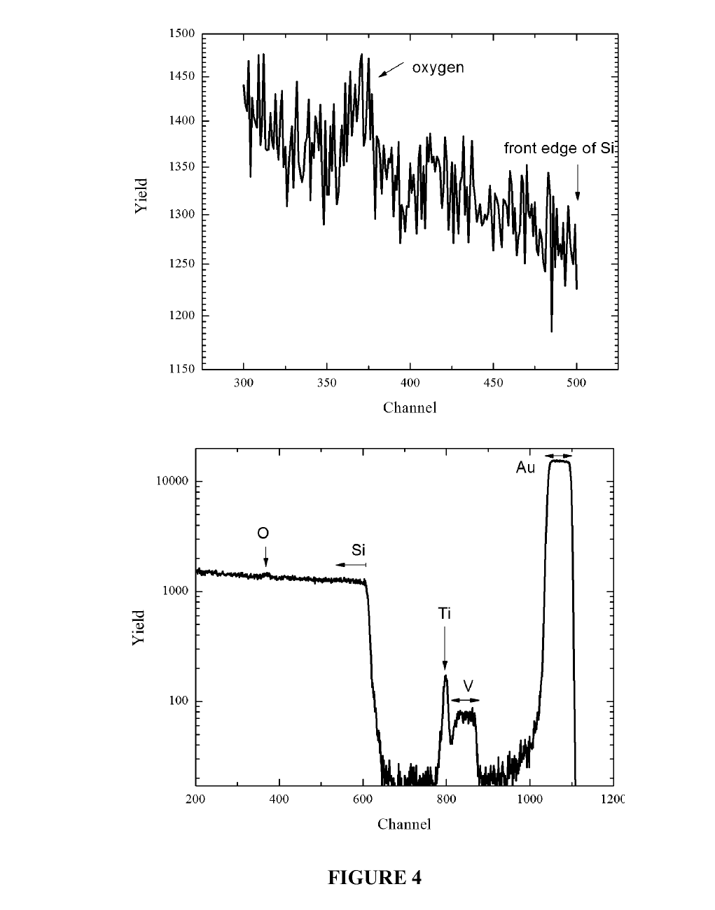

FIG. 4 shows a representative RBS spectrum obtained from one of the solid solution alloy films. Three signals are observed corresponding to scattering from Au and V in the film and from the underlying Ti layer. The compositions of the solid solution alloy films were determined to be 0.25, 0.65, 1.4, 2.2 and 4.6 at % V. The reactively sputtered films had 2.3 and 4.0 at % V.

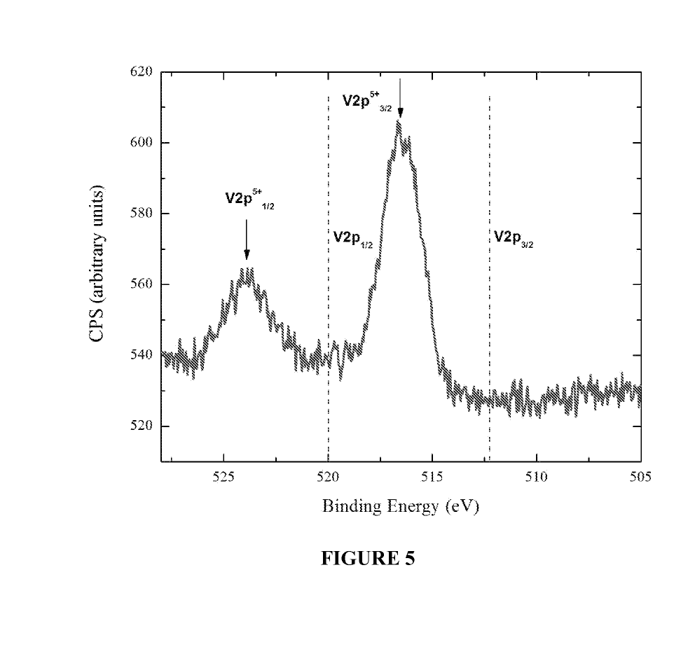

NER spectra acquired near the film-substrate interface and near the top of the Au—VOₓ films gave an O/V atomic ratio of 2.5±1.0 for both 2.3 and 4.0 at % V films, consistent with existence of V₂O₅. High resolution XPS spectra obtained from the Au—VOₓ films confirm the presence of V in the 5⁺ valence state. The V2p signal is comprised of two individual peaks as shown in FIG. 5. Both peaks are shifted up in binding energy from their atomic values. The chemical shift observed is consistent with the presence of V⁵⁺, supporting the NER results. There is no evidence in the spectrum for unbound V atoms. The slight asymmetry of the V2p_{3/2} peak is attributed to minor defect oxides such as V₂O₃. Similar results were obtained in the case of 15° X-ray incidence.

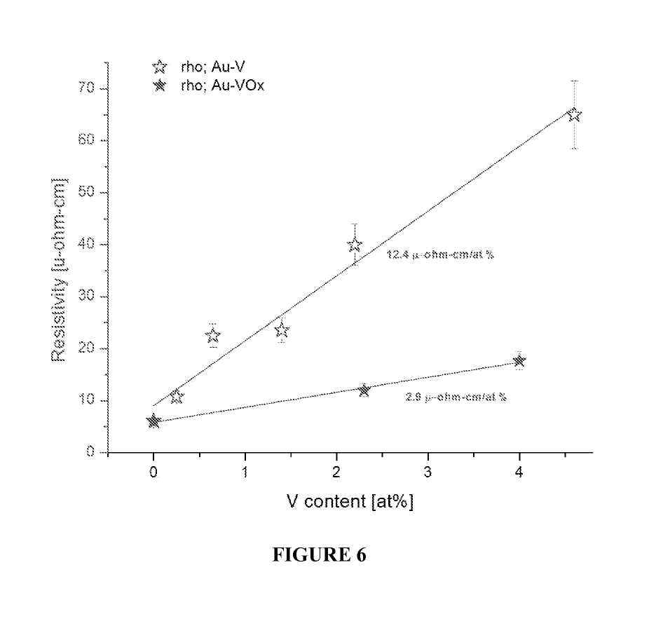

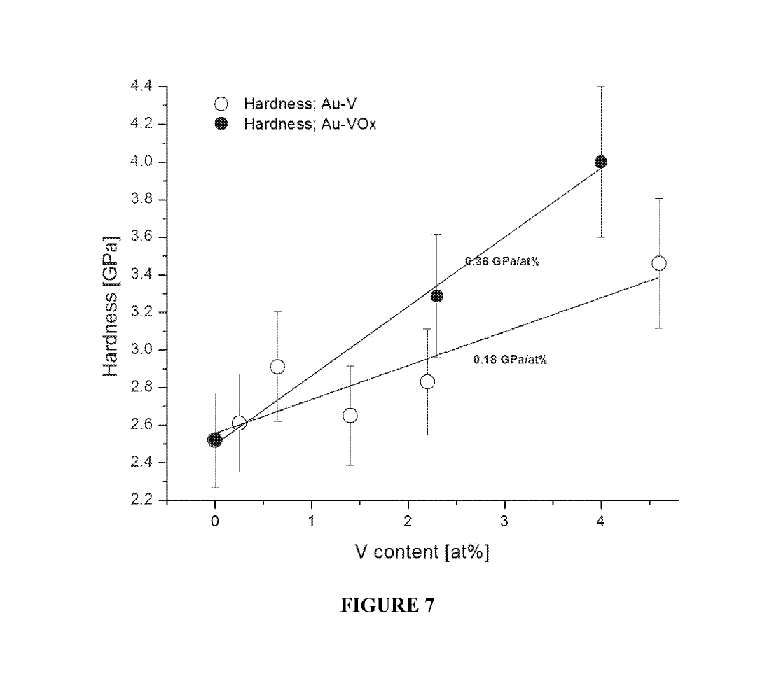

The results from electrical and mechanical measurements are presented in FIGS. 6-7, respectively. The pure Au film has a resistivity of 6±2 μΩ-cm (see, FIG. 6) as compared to 2.35 μΩ-cm for bulk Au. The discrepancy is not primarily due to a surface scattering effect, as is evident from the electron mean free path (˜40 nm at room temperature), which is much smaller than the film thickness. Instead, it is due to grain boundary scattering. The average grain size of all films in this study was approximately 35 nm, somewhat smaller than the bulk mean free path. The model of Mayadas and Shatzkes supports the significance of a grain boundary scattering contribution in this case. See, e.g. Mayadas, et al., Phys. Rev. B 1, 1382 (1970). In a simplified form, see, Lim, et al., Appl. Surf. Sci. 217, 95 (2003), the model predicts the film resistivity ρ_{g} as a function of the bulk resistivity ρ₀, the surface scattering coefficient p (here taken as zero), a parameter k=d/λ (d is film thickness and λ the bulk mean free path), and the parameter α=[(λR)/(d−dR)] (where R is the grain boundary reflection coefficient):

$${ρ}_{g} \approx {ρ}_{0} [ 1 + \frac{3}{8 k} ( 1 - p ) + \frac{3}{2} α ]$$

For our pure Au films with 500 nm thickness and an average resistivity of approximately 6 μΩ-cm, the model predicts an R value of 0.47, close to the average value of 0.4 found for Au across a number of other studies which, it should be noted, vary considerably in their findings. See, e.g. Cornely, et al., J. Appl. Phys. 49, 4094 (1978); van Attekum, et al., Phys. Rev. B 29, 645 (1984); de Vries, J. Phys. F 17, 1945 (1987); Schneider, et al., Appl. Phys. Lett. 69, 1327 (1996); and Zhang, et al. Phys Rev. B 74, 134109 (2006). The results herein are also consistent with a study in which pure Au with an average grain size of 39 nm, produced by an inert gas evaporation technique, had a resistivity of approximately 6 μΩ-cm at 300 K. See, e.g. Ederth, et al., J. Appl. Phys. 88, 6578 (2000). The grain size contribution to resistivity is uniform among our samples, so any additional resistivity in the alloy films must be attributed to the presence of V or V₂O₅.

The resistivity rises with increasing V concentration for both the solid solution and the Au—V₂O₅ films, as expected from the increased density of electron scattering centers. Based on the linear fit, the mean free path values for V atoms in solid solution at 2.3 and 4 at % are approximately 10.0 and 5.7 nm, respectively, assuming a V atomic volume of 8.77 cm³/mol. See, Handbook of Chemistry and Physics, 71^{st} Ed., edited by D. R. Lide, CRC Press, Boca Raton, Fla., 1990, pp. 4-115. The increase in resistivity due to scattering of electrons from imperfections in the lattice for a homogenous solid solution of low solute concentration is often given by the following formula:

ρ_{R}(X_{V})=CX_{V}

where C is the Nordheim coefficient and X_{V}=solute concentration. The measured resistivity data for the solid solution films was best-fitted to a straight line passing through the pure Au point, and CSS, the slope, was found to be 14.0 μΩ-cm/at % V. No published C value is available for Au—V, but the experimental value is comparable to that of Ti in Au: 12.4 μΩ-cm/at % Ti. As V is next to Ti in the periodic table, it might be expected that their Nordheim coefficients would be similar.

The Au—V₂O₅ resistivity is much lower for a given V concentration than Au—V. The slope of the Au—V₂O₅ line in FIG. 6 is only C_{ODS}=2.9 μΩ-cm/at % V. This indicates a significant reduction in the density of electron scattering centers consistent with the formation of discrete particles of V₂O₅ surrounded by a nearly solute-free matrix. This agrees with the chemical characterization results, and is an attractive attribute of the Au—V₂O₅ system for applications that demand high electrical conductivity. An order of magnitude estimate of the V₂O₅ particle size can be made by comparing the relative behavior of the solid solution and ODS films.

Assuming that the electron scattering cross section is the same as the physical particle cross section, and that there is no difference in the scattering behavior between V and V₂O₅ other than physical cross section, an approximate estimate of V₂O₅ particle size can be calculated for a given change in resistivity with respect to the Au—V. In one possible approach, the ratio of the resistivity slopes, C_{SS}/C_{ODS}, can be assumed to be the same as the ratio of the changes in electron mean free path as the V content changes in the two types of films. This leads to the conclusion that m, the number of V₂O₅ molecules in a single particle, is related to the atomic volume ratio V_{V2O5}/V_{V} such that

$${m}^{1 / 3} = \frac{1}{2} ( \frac{{C}_{SS}}{{C}_{ODS}} ) {( \frac{{V}_{V 2 O 5}}{{V}_{V}} )}^{2 / 3}$$

This results in an estimate of 515 V₂O₅ molecules per particle, and a particle radius of 2.2 nm. Although the assumptions made in this estimate are simplistic, the error in particle size is unlikely to be enormous as the radius only scales with the number of V₂O₅ units in a particle to the ⅓ power.

Like the resistivity, the hardness increases with increasing V content for all films (see FIG. 7]. As the grain size is uniform, the boundary strengthening contribution is approximately constant so any rise in hardness over that of pure Au can be attributed directly to the effect of the alloying. The hardness values have significant scatter, as seen in FIG. 7, so it is difficult to extract a functional dependence on V concentration. The reason for this is uncertain, but large scatter is typical based on prior experience with Au. A X_{Ru}^{2/3} dependence has previously been shown to match the behavior of Pt—Ru solid solution thin films with similar grain size. See, e.g. Hyun, et al., Acta Mater. 52, 4199 (2004). For Au—V films herein, either a X_{V}^{1/2} or X_{V}^{2/3} dependence fits reasonably well to the data, in keeping with the two main models for solid solution strengthening. See, e.g. Fleischer, Acta Metall. 9, 996 (1961). As neither model is superior, simple linear fits on the plot demonstrate the approximate dependence of hardness on V concentration over the range investigated.

The Au—V₂O₅ films show greater hardness at a given V concentration than the solid solution films. In accordance with the electrical results, this is commensurate with the strengthening effect of oxide dispersion. Assuming that the oxide particles are incoherent with the matrix, as is the case for prior studies of bulk ODS Au, the strengthening should follow the Orowan model for dislocation looping around obstacles. See, e.g. Dieter, “Mechanical Metallurgy,” ISBN: 0070168938, 3^{rd} Ed. (McGrawHill, New York, 1986). This model predicts that hardness is proportional to 1/L, where L is the average distance between particles, or equivalently to fₛ^{1/2}/r, where fₛ is particle volume fraction and r is particle radius. The volume fraction of V₂O₅ (5.8 and 9.8 vol % for the two cases studied) is simply proportional to the V concentration. Assuming that particle radius does not change appreciably with V concentration, a similar X_{V}^{1/2} functional dependence for both the solid solution and ODS films may be expected, with greater obstacle strength in the case of the oxide particles. Again, the large uncertainty associated with the mechanical measurements makes a precise match impossible, but a X_{V}^{1/2} dependence is a reasonable representation of the results.

The distance between particles that is important for dislocation pinning is not equivalent to the electron mean free path because a dislocation moves primarily on a plane and the pinning is mostly affected by planar nearest neighbor distances. See, e.g. Corti, et al., Int'l Met. Reviews 19, 77-88 (1974). Instead, it is a somewhat smaller value given by an expression such as the following:

L=1.25r\sqrt{2π/3f}

This spacing is 16.5 and 12.7 nm for the two ODS alloys herein. These values can be used to estimate the hardness increase due to the presence of the oxide particles. A commonly accepted version of the Orowan strengthening equation is as follows:

$$Δ H = \frac{2.43 MGb}{2 π \sqrt{1 - v}} ln ( \frac{2 r}{{r}_{0}} ) ( \frac{1}{L - 2 r} )$$

See, Nembach, “Particle Strengthening of Metals and Alloys,” ISBN 0-471-12072-3 (Wiley, New York, N.Y., 1997), pp. 235-251. Here, ΔH is the change in hardness, M is the Taylor factor for FCC metals, G is the shear modulus, b is the Burgers vector, v is the Poisson's ratio, and r₀ is the dislocation core radius. When appropriate values are inserted for the 2.3 V % ODS case, using an r value of 2.2 nm as estimated from the electrical behavior, the model predicts a hardness increase of 1.8 GPa as compared to the experimentally measured increase of 0.8 GPa over pure Au. Likewise, the predicted hardness increase for the 4.0 V % ODS alloy is 2.5 GPa as compared to the measured 1.5 GPa. An over prediction by a factor of 2 is common in other experimental studies, so this degree of agreement is reasonable.

In conclusion, the combination of high hardness and low resistivity that is possible to achieve in the Au—V₂O₅ films relative to the solid solution alloys demonstrates the attractiveness of this approach for fabricating wear-resistant micro-contacts. The electrical and mechanical behaviors are consistent with the chemical characterization, strongly indicating that the V₂O₅ is present in the form of small, closely-spaced nano-particles. A greater volume fraction of oxide particles is practical to produce than in bulk ODS alloys as thin films have no ductility requirement for fabrication into useful forms, which underscores the applicability of the ODS approach to thin film micro switch applications.

While this description is made with reference to exemplary embodiments, it will be understood by those skilled in the art that various changes may be made and equivalents may be substituted for elements thereof without departing from the scope. In addition, many modifications may be made to adapt a particular situation or material to the teachings hereof without departing from the essential scope. Also, in the drawings and the description, there have been disclosed exemplary embodiments and, although specific terms may have been employed, they are unless otherwise stated used in a generic and descriptive sense only and not for purposes of limitation, the scope of the claims therefore not being so limited. Moreover, one skilled in the art will appreciate that certain steps of the methods discussed herein may be sequenced in alternative order or steps may be combined. Therefore, it is intended that the appended claims not be limited to the particular embodiment disclosed herein.

1. A film comprising an alloy of gold and at least one of an oxide of a metal or an oxide of a semimetal.

2. The film according to claim 1, wherein at least one of an oxide of a metal or an oxide of a semimetal is selected from the group consisting of oxides of vanadium (V), aluminum (Al), zirconium (Zr), silicon (Si), magnesium (Mg), beryllium (Be), lithium (Li), boron (B), hafnium (Hf), thorium (Th), calcium (Ca), chromium (Cr), manganese (Mn), titanium (Ti), scandium (Sc), yttrium (Y), molybdenum (Mo), tungsten (W), zinc (Zn), niobium (Nb), tantalum (Ta), cerium (Ce), lanthanum (La), and combinations thereof.

3. The film according to claim 2, wherein the oxides of vanadium are selected from the group consisting of V₂O₅, V₂O₃, VO₂, and VO.

4. The film according to claim 1, wherein the film comprises less than about 99.9 at % gold and at least about 0.1 at % metal or semimetal.

5. The film according to claim 1, wherein the film comprises from about 1 at % to about 20 at % metal or semimetal.

6. The film according to claim 1, wherein the film has a thickness of from about 10 nm to about 25 μm.

7. A method of making a film comprising a step of simultaneously depositing gold and at least one metal or semimetal in an oxidative environment onto a substrate to thereby produce a film comprising an alloy of gold and at least one of an oxide of a metal or an oxide of a semimetal.

8. The method according to claim 7, wherein the oxidative environment comprises oxygen (O₂) such that at least a portion of the metal or semimetal is at least partially oxidized in situ to an oxide of the metal or an oxide of the semimetal.

9. The method according to claim 7, wherein the depositing step is selected from the group consisting of electrodeposition, physical vapor deposition, and chemical vapor deposition.

10. The method according to claim 9, wherein physical vapor deposition comprises sputter deposition.

11. The method according to claim 7, wherein the gold and the metal or semimetal are deposited in a co-sputtering arrangement in the presence of oxygen (O₂).

12. The method according to claim 7, wherein the at least one metal or semimetal is selected from the group consisting of vanadium (V), aluminum (Al), zirconium (Zr), silicon (Si), magnesium (Mg), beryllium (Be), lithium (Li), boron (B), hafnium (Hf), thorium (Th), calcium (Ca), chromium (Cr), manganese (Mn), titanium (Ti), scandium (Sc), yttrium (Y), molybdenum (Mo), tungsten (W), zinc (Zn), niobium (Nb), tantalum (Ta), cerium (Ce), lanthanum (La), and combinations thereof.

13. The method of claim 7, wherein the substrate is coated with an adhesion promoter.

14. An alloy of gold and at least one of an oxide of a metal or an oxide of a semimetal, wherein
the at least one of an oxide of a metal or an oxide of a semimetal is selected from the group consisting of oxides of vanadium (V), aluminum (Al), zirconium (Zr), silicon (Si), magnesium (Mg), beryllium (Be), lithium (Li), boron (B), hafnium (Hf), thorium (Th), calcium (Ca), chromium (Cr), manganese (Mn), titanium (Ti), scandium (Sc), yttrium (Y), molybdenum (Mo), tungsten (W), zinc (Zn), niobium (Nb), tantalum (Ta), cerium (Ce), lanthanum (La), and combinations thereof; and
the alloy comprises less than about 99.9 at % gold and at least about 0.1 at % metal or semimetal.

15. The alloy according to claim 14, wherein the oxides of vanadium are selected form the group consisting of V₂O₅, V₂O₃, VO₂, and VO.

16. A contact switch comprising at least two conductive electrodes, wherein at least a portion of at least one of the electrodes is coated with a film comprising an alloy of gold and at least one of an oxide of a metal or an oxide of a semimetal.

17. The contact switch according to claim 16, wherein the at least one of an oxide of a metal or an oxide of a semimetal is selected from the group consisting of oxides of vanadium (V), aluminum (Al), zirconium (Zr), silicon (Si), magnesium (Mg), beryllium (Be), lithium (Li), boron (B), hafnium (Hf), thorium (Th), calcium (Ca), chromium (Cr), manganese (Mn), titanium (Ti), scandium (Sc), yttrium (Y), molybdenum (Mo), tungsten (W), zinc (Zn), niobium (Nb), tantalum (Ta), cerium (Ce), lanthanum (La), and combinations thereof.

18. The contact switch according to claim 16, wherein the oxides of vanadium are selected form the group consisting of V₂O₅, V₂O₃, VO₂, and VO.

19. The contact switch according to claim 16, wherein the film comprises less than about 99.9 at % gold and at least about 0.1 at % metal or semimetal.

20. The contact switch according to claim 16, wherein the film has a thickness of from about 10 nm to about 25 μm.
